(19) United States
(12) Patent Application Publication
(10) Pub. No.: US 2008/0157359 A1
(43) Pub. Date: Jul. 3, 2008

(54) Crack-resistant solder joint, electronic component such as circuit substrate having the solder joint, semiconductor device, and manufacturing method of electronic component

(75) Inventors: Masato Yokobayashi, Tenri-shi (JP); Katsuyuki Tarui, Kasaoka-shi (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka-shi (JP)

(21) Appl. No.: 12/000,834

(22) Filed: Dec. 18, 2007

(30) Foreign Application Priority Data
Dec. 27, 2006 (JP) 2006-353290

(51) Int. Cl. H01L 23/488; H05K 1/00; B32B 15/00; B23K 1/20

(52) U.S. Cl. 257/737; 174/257; 428/646; 428/648; 228/173.1; 257/E23.023

(57) ABSTRACT

An electronic component according to the present invention includes a land 112 having a flat reference surface p1 and having a solder joint p3 to be solder bonded, wherein the solder joint p3 as a concave 113 recessed from the reference surface, and a nickel plate layer 114 is laminated on a surface of the land 112, and a position of an interface between (a) a tin-containing alloy layer 116 formed on the solder joint p3 of the nickel plate layer 114 in solder bonding the nickel plate layer 114 and (b) the nickel plate layer 114 deviates from a plane including the reference surface p1. This makes it possible to provide an electronic component including a solder joint which hardly cracks.

This Nonprovisional application claims priority under 35 U.S.C. §119(a) on Patent Application No. 353290/2006 filed in Japan on Dec. 27, 2006, the entire contents of which are hereby incorporated by reference.

### FIELD OF THE INVENTION

The present invention relates to a crack-resistant solder joint, an electronic component such as a circuit substrate having the solder joint, a semiconductor device, and a manufacturing method of the electronic component. Particularly, the present invention relates to a chip component, a circuit component, a substrate component, an electronic component, an electric component, and a semiconductor device, each of which is arranged so that a tin-containing solder is solder bonded to a metal plate layer such as a nickel plate or a gold plate provided on a land made of copper.

### BACKGROUND OF THE INVENTION

Conventionally, a solder containing tin (Sn) is used as a solder. Particularly, in recent, a lead-containing solder such as Sn—Pb alloy and Sn—Pb—Ag alloy has been used to bond an electronic component or the like.

However, a lead-free solder represented by Sn—Ag—Cu alloy has come to be used in consideration for environmental loading given by lead. However, a surface of copper (Cu) frequently used as a conductor pattern is likely to be oxidized. If the surface of copper is oxidized, wettability of the solder drops. Particularly in case of using the aforementioned lead-free solder, when the surface of copper is oxidized, the lead-free solder and the copper are less bonded to each other. Thus, there is a case where the copper land to be soldered is plated with gold (Au).

If the copper is directly plated with gold, a fragile alloy layer occurs. Thus, there is adopted a method in which: nickel plating is carried out as a barrier between a copper land used as a conductor pattern and a gold plate layer beforehand so as to suppress formation of the fragile alloy layer. For example, a document 1 (Japanese Unexamined Patent Publication No. 332408/2000 (Tokukai 2000-332408) (Publication date: Nov. 30, 2000)) discloses an arrangement in which the copper land is etched before carrying out the nickel plating in order to enhance a bonding property between the copper land and the nickel plate.

If the copper land having been subjected to the plating is bonded with the lead-free solder, metal melted by heat generated at the time of the solder bonding diffuses from each of both members, so that tin components of the solder diffusively enter into the nickel plate layer or the gold plate layer for example. Further, a tin-containing alloy layer made mainly of Cu—Sn alloy and Ni—Sn alloy is formed between the nickel plate layer and the gold player layer or between the gold plate layer and the tin-containing solder. The tin-containing alloy layer is fragile. Thus, a crack is likely to occur in case where a stress is exerted to the solder joint.

Particularly, a vertical elastic coefficient of nickel is so large as about 200 kN/mm², so that a stress is likely to be concentrated onto an interface between the nickel plate layer and the tin-containing alloy layer. Thus, a crack is likely to occur particularly in the interface between the nickel plate layer and the tin-containing alloy layer.

An example of a technique for preventing a stress exerted to a structure having such a fragile alloy layer from generating a crack is a method disclosed by a document 2 (Japanese Unexamined Patent Publication No. 188313/2003 (Tokukai 2003-188313) (Publication date: Jul. 4, 2003)). The document 2 discloses a technique in which a metal portion to be bonded with solder is made thicker so that a region free from any Cu—Sn alloy formed in carrying out solder bonding remains on a metal wiring portion. This technique prevents the metal wiring from cracking.

However, the conventional method does not consider any method for fundamentally avoiding the crack which is likely to be generated by the tin-containing alloy layer formed in carrying out the solder bonding.

According to the method of the document 2 for example, the region free from any Cu—Sn alloy remains on the metal wiring portion, so that it is possible to prevent the metal wiring from being cracked by a heat stress generated by a difference in the thermal expansion coefficient and the like of members constituting the substrate. However, there is no solution as to a stress exerted to a region where the Cu—Sn alloy is formed, and such a problem that a crack is likely to occur in the tin-containing alloy layer including the Cu—Sn alloy remains unsolved.

### SUMMARY OF THE INVENTION

In view of the foregoing conventional problems, the present invention was made, and an object of the present invention is to provide a crack-resistant solder joint, an electronic component such as a circuit substrate having the solder joint, a semiconductor device, and a manufacturing method of the electronic component.

According to the conventional method, no attention is paid to the tin-containing alloy layer which is likely to crack and a position of an interface between the tin-containing alloy layer and the nickel plate layer. A position of the tin-containing alloy layer or the like which is likely to crack is substantially the same as a position of a surface of the copper land which has not been etched.

As a result of diligent study carried out by the present inventors, they found that the crack is less likely to occur if the position of the tin-containing alloy layer or the like which is likely to crack is separated away from the position in which the stress causing the crack is concentrated. Further, they studied the position of the tin-containing alloy layer and the position of the interface between the tin-containing alloy layer and the nickel plate layer, thereby separating the portion which is likely to crack from the position in which the stress is concentrated. As a result, occurrence of direct crack in the solder joint can be suppressed.

In order to achieve the foregoing object, an electronic component of the present invention comprises an electrode having a flat reference surface and a solder joint to be solder bonded, and the solder joint has a concave recessed from the reference surface, and one or more metal layers are laminated on a surface of the concave, and a position of an interface between (a) a tin alloy layer formed on a surface of the metal layer in solder bonding the metal layer and (b) the metal layer deviates from a plane including the reference surface.

With the above-described arrangement, in the electronic component of the present invention, the position of the interface between (a) the tin alloy layer formed on the surface of the metal layer in solder bonding the metal layer and (b) the metal layer deviates from the plane including the reference surface. For example, if the metal layer is positioned so high that its thickness is larger than the depth of the concave, the interface between the tin alloy layer and the metal layer is provided outside the concave. If the metal layer is positioned so low that its thickness is smaller than the depth of the concave, the interface between the tin alloy layer and the metal layer is provided inside the concave.

The tin alloy layer generated on the metal layer by solder bonding is fragile with respect to a mechanical stress and is likely to crack. However, the foregoing arrangement allows a mechanical stress exerted to the tin alloy layer and the interface between the tin alloy layer and the metal layer to be partially alleviated, so that it is possible to prevent the solder from cracking in the structurally fragile tin alloy layer and the interface between the tin alloy layer and the metal layer.

Further, in order to achieve the foregoing object, an electronic component of the present invention comprises an electrode having a flat reference surface and a solder joint to be solder bonded, and the solder joint has a concave recessed from the reference surface, and the solder joint has the metal layers including a first metal layer and a second metal layer laminated sequentially from the surface of the concave, and a position of an interface between the first metal layer and the second metal layer in solder bonding the metal layers deviates from a plane including the reference surface.

With the above-described arrangement, tin components of the solder diffusively enter into the second metal layer. Thus, an amount of tin components which diffusively enter into the first metal layer decreases, so that the tin alloy layer is formed between the first metal layer and the second metal layer.

That is, also in this case, it is possible to partially alleviate the mechanical stress, exerted to the tin alloy layer and the interface thereof, which is caused by the solder bonding, so that it is possible to prevent the solder from cracking in the structurally fragile tin alloy layer and the interface between the tin alloy layer and the metal layer.

In order to achieve the foregoing object, a semiconductor device of the present invention has the electronic component, and the solder junction of the electronic component is solder bonded to a semiconductor element.

With the above-described arrangement, it is possible to prevent the solder from cracking, so that the connection reliability of the solder joint is greatly improved. Thus, the connection reliability of the solder joint of the manufactured semiconductor device is greatly improved, so that an yield in manufacturing a circuit with the semiconductor device is improved. Further, a reliability of the manufactured device with the semiconductor device and an yield in manufacturing a device with the semiconductor device are improved.

In order to achieve the foregoing object, a solder joint of the present invention is provided on an electrode having a flat reference surface, and the solder joint has a concave recessed from the reference surface, and one or more metal layers are laminated on a surface of the concave, and a position of an interface between (a) a tin-containing alloy layer formed on a surface of the metal layer in solder bonding the metal layer and (b) the metal layer deviates from a plane including the reference surface.

With the above-described arrangement, the position of the interface between (a) the tin alloy layer formed on the surface of the metal layer in solder bonding the metal layer and (b) the metal layer deviates from the plane including the reference surface. For example, if the metal layer is positioned so high that its thickness is larger than the depth of the concave, the interface between the tin alloy layer and the metal layer is provided outside the concave. If the metal layer is positioned so low that its thickness is smaller than the depth of the concave, the interface between the tin alloy layer and the metal layer is provided inside the concave.

The tin alloy layer generated on the metal layer by solder bonding is fragile with respect to a mechanical stress and is likely to crack. However, the foregoing arrangement allows a mechanical stress exerted to the tin alloy layer and the interface between the tin alloy layer and the metal layer to be partially alleviated, so that it is possible to prevent the solder from cracking in the structurally fragile tin alloy layer and the interface between the tin alloy layer and the metal layer.

In order to achieve the foregoing object, a solder joint is provided on an electrode having a flat reference surface, and the solder joint has a concave recessed from the reference surface, and a first metal layer and a second metal layer are laminated sequentially from the surface of the concave, and a position of an interface between the first metal layer and the second metal layer in solder bonding the metal layers deviates from a plane including the reference surface.

With the above-described arrangement, tin components of the solder diffusively enter into the second metal layer. Thus, an amount of tin components which diffusively enter into the first metal layer decreases, so that the tin alloy layer is formed between the first metal layer and the second metal layer.

That is, also in this case, it is possible to partially alleviate the mechanical stress, exerted to the tin alloy layer and the interface thereof, which is caused by the solder bonding, so that it is possible to prevent the solder from cracking in the structurally fragile tin alloy layer and the interface between the tin alloy layer and the metal layer.

A method of the present invention for manufacturing an electronic component comprises the steps of: (i) forming a concave recessed in an electrode having a flat reference surface; (ii) forming one or more metal layers on a surface of the concave; and (iii) solder bonding the metal layer, wherein the metal layer is positioned higher than the reference surface in the step (ii), and a position of an interface between (a) a tin alloy layer formed on the metal layer and (b) the metal layer deviates from a plane including the reference surface in the step (iii).

Further, a method of the present invention for manufacturing an electronic component comprises the steps of: (i) forming a concave recessed in an electrode having a flat reference surface; (ii) forming one or more metal layers on a surface of the concave; and (iii) solder bonding the metal layer, wherein the metal layer is positioned lower than the reference surface in the step (ii), and a position of an interface between (a) a tin alloy layer formed on the metal layer and (b) the metal layer deviates from a plane including the reference surface in the step (iii).

With the above-described arrangement, the position of the tin alloy layer which is fragile with respect to a mechanical stress and the position of the interface between the tin alloy layer and the metal layer can be deviated from the plane including the reference surface. This makes it possible to partially alleviate the mechanical stress exerted to the tin alloy layer and the interface between the tin alloy layer and the metal layer. That is, it is possible to prevent the solder from cracking in the structurally fragile tin alloy layer and the interface between the tin alloy layer and the metal layer.

A method of the present invention for manufacturing an electronic component comprises the steps of: (i) forming a concave recessed in an electrode having a flat reference surface; (ii) forming one or more metal layers on a surface of the concave; and (iii) solder bonding the metal layer, wherein a first metal layer is provided on the surface of the concave so as to be positioned higher than the reference surface and a second metal layer is further provided in the step (ii), and a position of an interface between the first metal layer and the second metal layer deviates from a plane including the reference surface in the step (iii).

Further, a method of the present invention for manufacturing an electronic component comprises the steps of: (i) forming a concave recessed in an electrode having a flat reference surface; (ii) forming one or more metal layers on a surface of the concave; and (iii) solder bonding the metal layer, wherein a first metal layer is provided on the surface of the concave so as to be positioned lower than the reference surface and a second metal layer is further provided in the step (ii), and a position of an interface between the first metal layer and the second metal layer deviates from a plane including the reference surface in the step (iii).

With the above-described arrangement, the tin alloy layer which is fragile with respect to a mechanical stress is formed between the first metal layer and the second metal layer, and the interface can be deviated from the plane including the reference surface. This makes it possible to partially alleviate the mechanical stress exerted to the tin alloy layer and the interface between the tin alloy layer and the metal layer. That is, it is possible to prevent the solder from cracking in the structurally fragile tin alloy layer and the interface between the tin alloy layer and the metal layer.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1(a) is a cross sectional view illustrating an arrangement of a solder joint of a semiconductor device in an embodiment.

FIG. 1(b) is a cross sectional view illustrating an arrangement of a solder joint of a semiconductor device in an embodiment.

FIG. 1(c) is a cross sectional view illustrating an arrangement of a solder joint of a semiconductor device in an embodiment of the present invention.

FIG. 2 shows cross sectional views illustrating types of a solder joint of a semiconductor device in an embodiment.

FIG. 3 is a cross sectional view of a semiconductor device having the solder joint of FIG. 1.

FIG. 4 is a cross sectional view illustrating a state in which a circuit substrate of the semiconductor device of FIG. 4 is bonded with a tin-containing solder.

FIG. 5 is an enlarged cross sectional view illustrating a joint between the circuit substrate of the semiconductor device of FIG. 4 and the tin-containing solder.

FIG. 6(a) is a cross sectional view illustrating an arrangement of a metal plate layer of FIG. 1.

FIG. 6(b) is a cross sectional view illustrating another arrangement of the metal plate layer of FIG. 1.

FIG. 7(a) is a cross sectional view illustrating how to form the circuit substrate of the semiconductor device of FIG. 1(a) and how to carry out solder bonding.

FIG. 7(b) is a cross sectional view illustrating how to form the circuit substrate of the semiconductor device of FIG. 1(a) and how to carry out solder bonding.

FIG. 7(c) is a cross sectional view illustrating how to form the circuit substrate of the semiconductor device of FIG. 1(a) and how to carry out solder bonding.

FIG. 7(d) is a cross sectional view illustrating how to form the circuit substrate of the semiconductor device of FIG. 1(a) and how to carry out solder bonding.

FIG. 7(e) is a cross sectional view illustrating how to form the circuit substrate of the semiconductor device of FIG. 1(a) and how to carry out solder bonding.

FIG. 8(a) is a cross sectional view illustrating how to form the circuit substrate of the semiconductor device of FIG. 1(b) and how to carry out solder bonding.

FIG. 8(b) is a cross sectional view illustrating how to form the circuit substrate of the semiconductor device of FIG. 1(b) and how to carry out solder bonding.

FIG. 8(c) is a cross sectional view illustrating how to form the circuit substrate of the semiconductor device of FIG. 1(b) and how to carry out solder bonding.

FIG. 8(d) is a cross sectional view illustrating how to form the circuit substrate of the semiconductor device of FIG. 1(b) and how to carry out solder bonding.

FIG. 8(e) is a cross sectional view illustrating how to form the circuit substrate of the semiconductor device of FIG. 1(b) and how to carry out solder bonding.

FIG. 9 is a cross sectional view illustrating a semiconductor device in another embodiment which semiconductor device is obtained by providing semiconductor joints on both surfaces of the semiconductor device of FIG. 3.

FIG. 10 is a cross sectional view illustrating a semiconductor device in another embodiment which semiconductor device is obtained by connecting the circuit substrate to another semiconductor device.

FIG. 11 is a cross sectional view illustrating Example, in which connection reliability of the solder joint of the semiconductor device of the embodiment is evaluated, so as to illustrate a state in which a load is applied to the solder joint of the semiconductor device formed as illustrated in FIG. 1(a).

FIG. 12 is a graph illustrating results of Example, in which connection reliability of the solder joint of the semiconductor device of the embodiment is evaluated, wherein the graph is obtained by plotting joint interface fracture coefficients with respect to layer thickness differences.

### DESCRIPTION OF THE EMBODIMENTS

### Embodiment 1

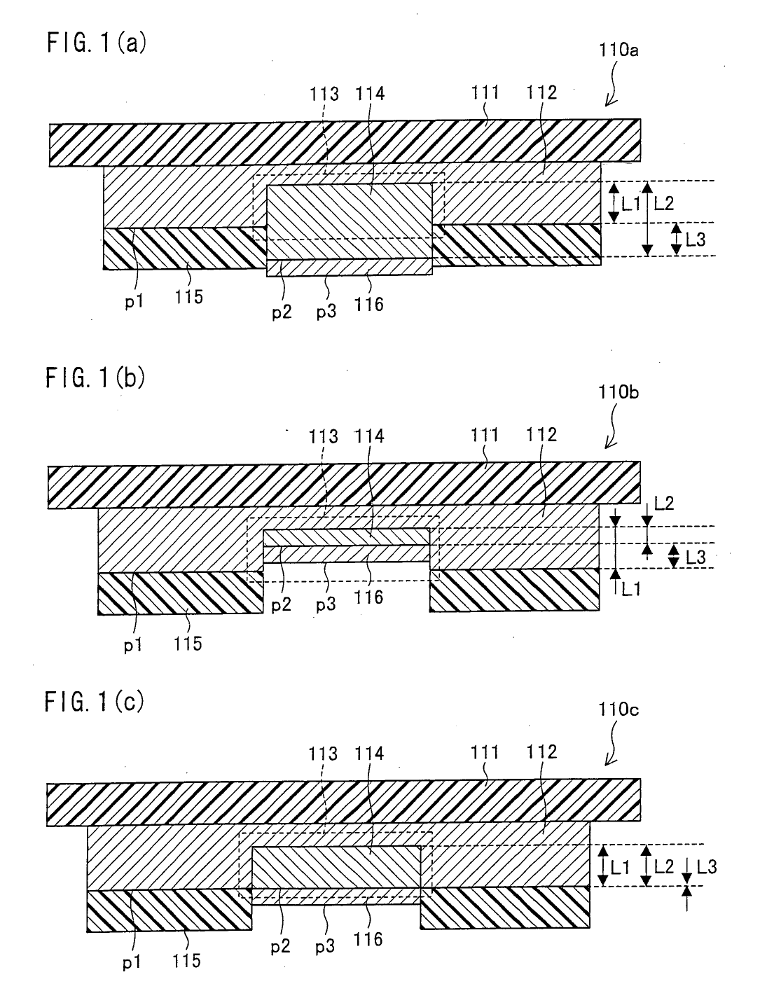

With reference to FIG. 1 to FIG. 7, the following description will explain an embodiment of the present invention.

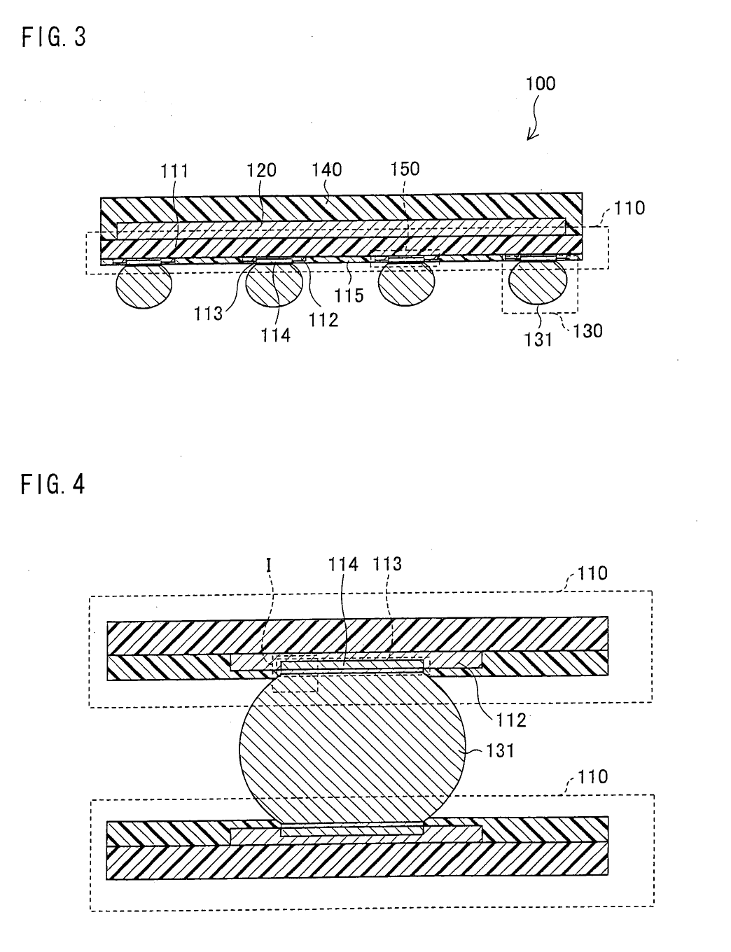

FIG. 3 is a cross sectional view of a semiconductor device 100 of the present embodiment. The semiconductor device 100 of the present embodiment includes a circuit substrate 110, a semiconductor chip 120, and external connection terminals 130. The circuit substrate 110 has a wiring layer (not shown) provided on the circuit substrate 110, and the semiconductor chip 120 is provided thereon. As the substrate 111, a known material may be used. For example, a glass substrate or an epoxy substrate may be used. Further, the wiring layer can be formed by a known method. For example, the wiring layer can be formed by etching a copper foil or an aluminum foil. Further, the wiring layer may be formed in a multi-layer manner as necessary.

Further, the semiconductor chip 120 can be connected to the wiring layer by a known method. For example, the wiring layer may be connected by solder bonding or may be connected by a known flip bonding. Note that, a resin 140 for protecting the semiconductor chip 120 and the like may be provided on the circuit substrate 110 so as to be positioned on the side where the semiconductor chip 120 is provided.

Further, the circuit substrate 110 of the present embodiment includes the external connection terminals 130 each of which is positioned on a surface different from the surface having the semiconductor chip 120 of the substrate 111 and which allows electrical connection with the semiconductor device 100 of the present embodiment, and the circuit substrate 110 is electrically connected to the semiconductor chip 120. The circuit substrate 110 of the present embodiment may be arranged so that a wiring (not shown) is provided so as to be positioned on the side where the external connection terminals 130 of the substrate 111 are formed or may be arranged so that the wiring extends through a via hole from the wiring layer on the side where the semiconductor chip 120 is formed to a surface of the substrate 111 where the external connection terminals 130 are formed. These wirings can be formed by etching, for example, a copper foil or an aluminum foil in accordance with a known method. A solder joint 150 is formed on a portion in which the wiring is connected to each of the external connection terminals 130 or-other electronic component.

The solder joint 150 is an electrode provided so as to connect the wiring (not shown) to the external connection terminal 130 or other electronic component, and a land 112 is formed on the solder joint 150. The land 112 may be subjected to a process for improving wettability of the solder as described later.

The present embodiment describes a case where the land 112 constituting the wiring is made of copper (Cu), but the land 112 may be made of alloy containing copper, aluminum, or other metal.

In the portion where the land 112 is solder bonded, a concave 113 is formed. If the surface of the land 112 is regarded as a flat reference surface, the concave 113 is formed so as to be recessed into a direction of the surface of the substrate 111. The concave 113 can be formed by a known method, but etching may be carried out for example.

Further, the concave 113 is plated with metal. In case of carrying out the solder bonding, the plated concave 113 improves the wettability. In plating the concave 113, wet plating carried out in an electric manner or a chemical manner may be adopted or dry plating carried out with vapor deposition may be adopted.

The plate layer formed on the concave 113 is not particularly limited as long as the plate layer is made of metal which realizes the foregoing object, so that metal containing nickel (Ni) or gold (Au) may be used. The concave 113 may be plated with plural kinds of metal or alloy. In case of plating the concave 113 with gold, it may be so arranged that the land is plated with nickel and the resultant is plated with gold. In the semiconductor device 100 of the present embodiment, the nickel plating is carried out so as to form a nickel plate layer 114. The nickel plate layer 114 can be formed by a known method, e.g., by electroless plating or a similar method.

In the semiconductor device 100 of the present embodiment, a depth of the concave 113 of the land 112 formed on the circuit substrate 110 and a thickness of the nickel plate layer 114 are important. This will be detailed later.

Further, a portion other than the portion where the land 112 is solder bonded on the surface of the substrate 111 is covered by a solder resist 115. The solder resist 115 is a member for protecting the wiring on the substrate 111. Any material can be used to constitute the solder resist 115 as long as the material is a known material having an insulating property.

In the semiconductor device 100 of the present embodiment, the external connection terminal 130 is made of a tin (Sn)-containing solder 131. As the tin-containing solder 131, it is preferable to use a solder generally referred to as “lead-free solder”. An example thereof is a tin-containing solder made of Sn—Ag—Cu alloy. As the tin-containing solder 131 of the present embodiment, it is preferable to use the tin-containing lead-free solder containing the Sn—Ag—Cu alloy, but it is possible to use a conventional solder containing lead, e.g., Sn—Pb alloy or Sn—Pb—Ag alloy.

The semiconductor device 100 of the present embodiment is arranged so that the land 112 formed in this manner and the tin-containing solder 131 serving as the external connection terminal 130 are bonded with each other by solder bonding.

For example, the semiconductor device 100 of the present embodiment is connected to another semiconductor device by the tin-containing solder 131.

FIG. 4 is a cross sectional view illustrating a state in which the circuit substrate 110 of the semiconductor device 100 of the present embodiment is bonded by the tin-containing solder 131. In FIG. 4, the semiconductor chip 120 and the like are not illustrated so as to simplify descriptions.

FIG. 4 illustrates a state in which two circuit substrates 110 are bonded to each other by the tin-containing solder 131. In case of bonding the two circuit substrates 110 in the foregoing manner, the tin-containing solder 131 formed on the one of the circuit substrates 110 is used, so that it is not necessary to provide another tin-containing solder 131 on the other one of the circuit substrates 110.

Further, in FIG. 4, the circuit substrates 110 of the present embodiment are bonded with each other, but it may be so arranged that the circuit substrate 110 is bonded with another known semiconductor device by the tin-containing solder 131.

In the semiconductor device 100 of the present embodiment, the depth of the concave 113 of the land 112 formed on the circuit substrate 110 and the thickness of the nickel plate layer 114 hardly cause occurrence of crack in the solder joint of the semiconductor device.

Before describing the depth of the concave 113 of the land 112 formed on the circuit substrate 110 and the thickness of the nickel plate layer 114, the following describes a structure formed on the region where the nickel plate layer and the tin-containing solder are solder bonded to each other with reference to FIG. 5.

FIG. 5 is an enlarged view of a region I illustrated in FIG. 4. FIG. 5 is a cross sectional view illustrating the region I which is a part of the region where the solder bonding is carried out in FIG. 4. This cross sectional view shows that: the nickel plate layer 114 is provided on the land 112, and the tin-containing solder 131 is solder bonded to the nickel plate layer 114. The solder resist 115 is provided on the surface of the land 112 so as to be positioned in a region which is not used for the solder bonding. An interface between the land 112 and the solder resist 115, i.e., a surface position of the land 112 which surface position is free from the concave 113 (that is, a position of the original surface where the concave has not been formed) is p1. If the surface of the land 112 is flat, p1 is in the same level as the flat surface (reference surface) of the land 112.

Between the nickel plate layer 114 and the tin-containing solder 131, both the nickel plate layer 114 and the tin-containing solder 131 that were melted at the time of the solder bonding diffuse, so that tin components of the solder come into the nickel plate layer. As a result, the tin-containing alloy layer 116 is formed. An interface between the nickel plate layer 114 and the tin-containing alloy layer 116 is p2. Further, an interface between the tin-containing alloy layer 116 and the tin-containing solder 131 is p3.

The tin-containing alloy layer 116 formed in the foregoing manner is an alloy layer made of (a) components included in the tin-containing solder 131 and (b) components included in the nickel plate layer 114. Depending on the thickness of the nickel plate layer 114, the alloy layer may contain components included in the land 112.

Note that, the present embodiment describes the case where the tin-containing solder 131 is solder bonded on the nickel plate layer 114. However, in case where a layer plated with gold or the like for example is further provided on the nickel plate layer 114, the tin-containing alloy layer 116 is formed as an alloy layer made of such metals.

Anyway, the tin-containing alloy layer 116 is fragile and a crack is likely to occur in case where a stress is exerted to the solder joint. Thus, the present embodiment describes the tin-containing alloy layer 116 which appears between the nickel plate layer 114 and the tin-containing solder 131.

Depending on conditions of the solder bonding, the thickness of the tin-containing alloy layer 116 varies. However, the present embodiment gives descriptions on the basis of such condition that the thickness of the tin-containing alloy layer 116 is about 2 to 4 μm.

As a result of diligent study carried out by the present inventors, they found that the crack hardly occurs as long as a position of the tin-containing alloy layer or the like which is likely to crack is separated from a position on which a stress causing the crack is concentrated. Further, they found that the crack hardly occurs if the interface p2 and the position of the tin-containing alloy layer 116 are deviated from the interface p1.

That is, in the semiconductor device 100 of the present embodiment, due to the following arrangement, the crack hardly occurs in the interface p2 and the tin-containing alloy layer 116 that are formed in the solder joint.

FIG. 1(a) to FIG. 1(c) are cross sectional views each of which illustrates a structure of the solder joint of the semiconductor device 100 of the present embodiment and each of which shows the depth of the concave 113 of the land 112 formed on the circuit substrate 110 and the thickness of the nickel plate layer 114.

The size of the concave 113 of the land 112 is represented as a concave depth L1, the thickness of the nickel plate layer 114 is represented as a nickel plate thickness L2, and a size difference between the concave depth L1 and the nickel plate thickness L2 is a layer thickness difference L3. Under this condition, the solder joint structure of the semiconductor device 100 of the present embodiment is categorized into the following three types respectively illustrated in FIG. 1(a) to FIG. 1(c).

Note that, FIG. 1 does not illustrate the tin-containing solder 131 so that the positional relation of the members is understood not in a complicate manner, but the tin-containing solder 131 is provided so as to be in contact with the interface p3 on the tin-containing alloy layer 116.

FIG. 1(a) illustrates a structure of a circuit substrate 110a in which the concave 113 is formed in the land 112 so that the thickness of the nickel plate layer 114 is larger than the depth of the concave 113. That is, the concave depth L1 is relatively small, and the nickel plate thickness L2 is large. This arrangement is realized by setting at least either the depth of the concave 113 or the thickness of the nickel plate layer 114.

In the present embodiment, the land 112 is made of copper, so that the interface p2 is positioned outside the concave 113 of the land 112 made of copper. In the present embodiment, the interface p2 is formed outside the concave 113, and the case where the layer thickness difference L3 is equal to or larger than 1 μm, that is, a state in which the interface p1 and the interface p2 are deviated from each other by 1 μm or longer is defined as a cross sectional shape A.

Further, the tin-containing alloy layer 116 is formed on the surface of the nickel plate layer 114 in FIG. 1(a), and the interface p3 between the tin-containing alloy layer 116 and the tin-containing solder 131 is formed inside a layer of the solder resist 115 in FIG. 1(a), but the interface p3 may be formed outside the solder resist 115.

Next, FIG. 1(b) illustrates a circuit substrate 110b in which the concave 113 is formed in the land 112 so that the thickness of the nickel plate layer 114 is smaller than the depth of the concave 113. That is, the concave depth L1 is relatively large, and the nickel plate thickness L2 is small. This arrangement is realized by setting at least either the depth of the concave 113 or the thickness of the nickel plate layer 114.

In the present embodiment, the land 112 is made of copper, so that the interface p2 is formed inside the concave 113 of the land 112 made of copper. The interface p2 is formed inside the concave 113 in this manner, and a state in which the thickness difference L3 is equal to or larger than 1 μm, that is, a state in which the interface p1 and the interface p2 are deviated from each other by 1 μm or longer is defined as a cross sectional shape B.

Further, the tin-containing alloy layer 116 is formed on the surface of the nickel plate layer 114 in FIG. 1(b), and the interface p3 between the tin-containing alloy layer 116 and the tin-containing solder 131 is formed inside the concave 113. The thickness of the tin-containing alloy layer 116 of the present embodiment is about 2 to 4 μm, so that the interface p3 may be formed outside the concave 113 as well as the case of FIG. 1(b).

Next, FIG. 1(c) illustrates a structure of a circuit substrate 110c in which the concave 113 is formed in the land 112 so that the thickness of the nickel plate layer 114 is substantially the same as the depth of the concave 113. That is, FIG. 1(c) illustrates a case where the concave depth L1 and the nickel plate thickness L2 are substantially the same. That is, this is a case where the interface p2 is formed near to the interface p1 between the land 112 and the solder resist 115. In the present embodiment, a state in which the layer thickness difference L3 is smaller than 1 μm is defined as a cross sectional shape C.

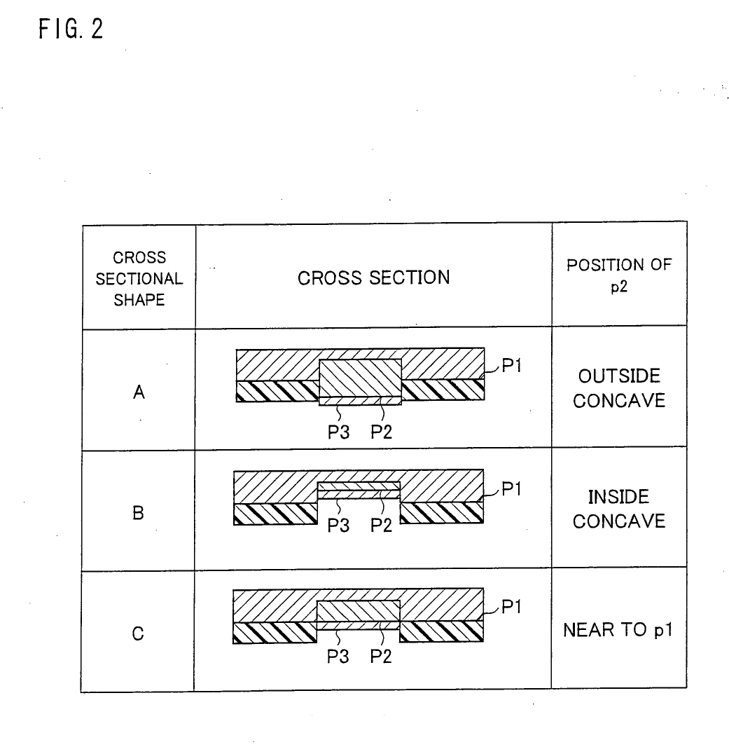

The aforementioned cross sectional shapes and the position of the interface p2 are illustrated in FIG. 2.

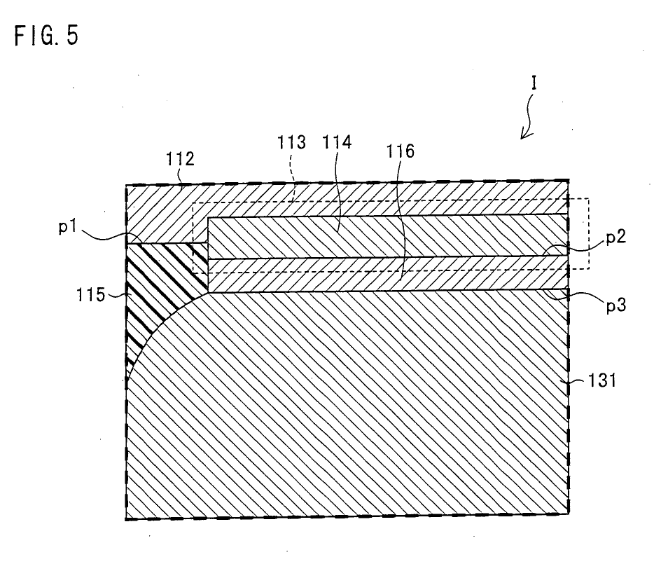

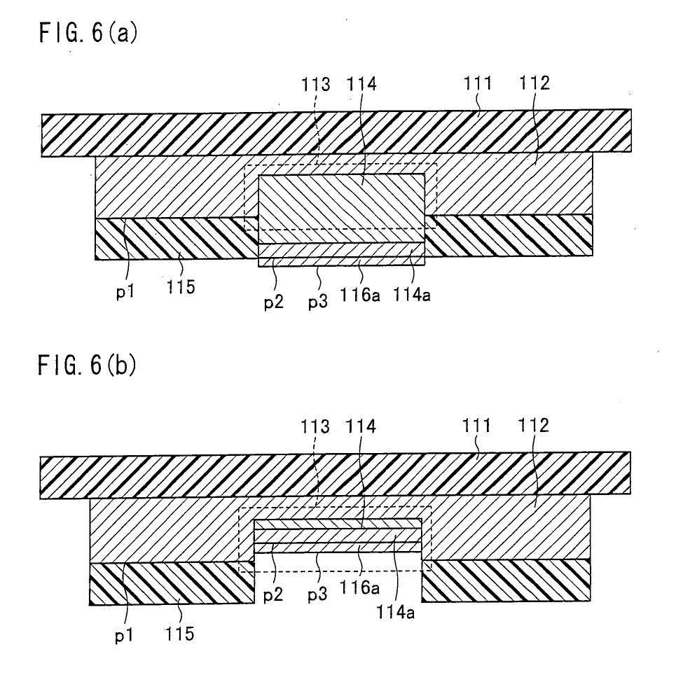

Note that, as illustrated in FIG. 6(a) and FIG. 6(b), a gold plate layer 114a may be further formed on the nickel plate layer 114 as the metal plate layer formed on the concave 113. FIG. 6(a) and FIG. 6(b) are a cross sectional view showing a modification example of the metal plate layer in the solder joint structure illustrated in FIG. 1(a) and FIG. 1(b).

If the gold plate layer 114a is formed in this manner, it is possible to improve the wettability of the metal plate layer with respect to the tin-containing solder 131 such as a lead-free solder without being influenced by the fragile alloy layer in forming the gold plate layer 114a directly on the land 112 made of copper.

Further, if the metal plate layer is formed as illustrated in FIG. 6(a) and FIG. 6(b), the tin-containing solder 131 is solder bonded to the gold plate layer 114a. In this case, tin components of the tin-containing solder 131 diffusively enter into the gold plate layer 114a. Thus, an amount of tinny components which diffusively enter into the nickel plate layer 114 decreases. That is, the tin-containing alloy layer 116a is likely to be formed on the gold plate layer 114a so as to be positioned between the gold plate layer 114a and the nickel plate layer 114.

Further, depending on the thickness of the gold plate layer 114a and the solder bonding condition, the gold plate layer 114a may fail to remain on a solder bonded face after the solder bonding. In this case, the operation is based on the illustrations of FIG. 1(a) and FIG. 1(b). Also in case where the gold plate layer 114a remains after the solder bonding, the tin-containing alloy layer 116a may be positioned with reference to the illustrations of FIG. 1(a) and FIG. 1(b).

The present embodiment mainly describes the solder joint structure illustrated in FIG. 1(a) to FIG. 1(c), but the gold plate layer may be formed in any embodiment as illustrated in FIG. 6(a) and FIG. 6(b).

The present embodiment mainly describes the case of the cross sectional shape A.

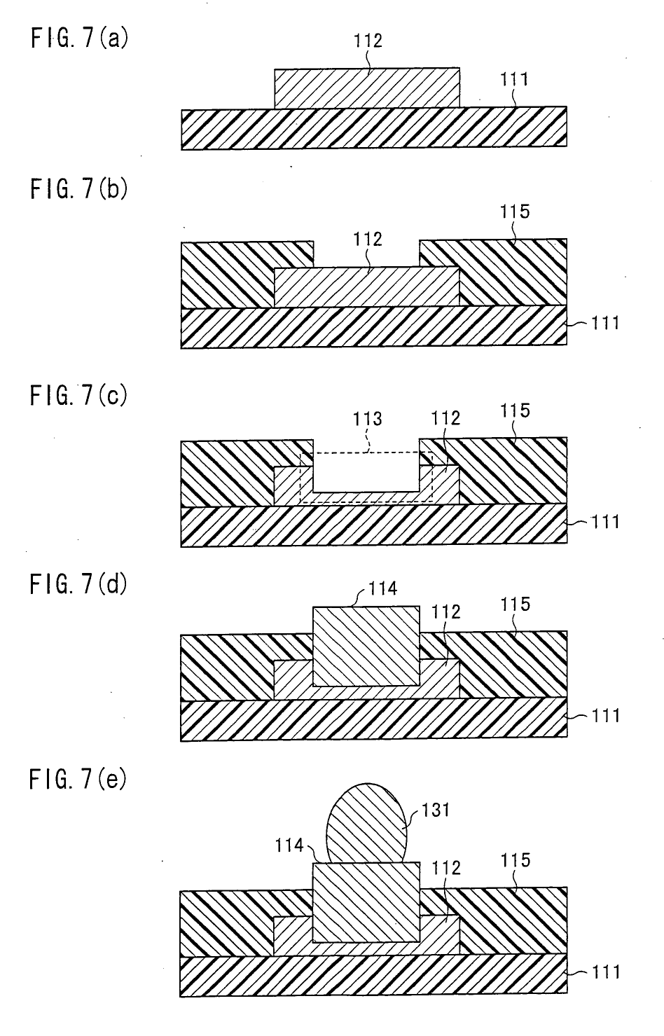

Next, the following will explain how to carry out the solder bonding as in the cross sectional shape A with reference to FIG. 7.

FIG. 7 is a cross sectional view illustrating a procedure in which the circuit substrate 110a is formed into the cross sectional shape A so as to carry out the solder bonding.

First, as illustrated in FIG. 7(a), a portion where solder bonding is carried out with respect to a wiring line (i.e., land 112) is formed on a substrate 111 made of a known material such as a glass substrate or an epoxy substrate. Any material may be used to constitute the wiring as long as the material is a known conductive material. Examples of the material include copper and aluminum. Further, the wiring is formed by a known method. For example, a conductor thin film such as a copper foil formed on the substrate 111 is etched so as to form the wiring or a printed wiring is transferred onto the substrate 111. Other known method may be adopted so as to form the wiring.

Next, as illustrated in FIG. 7(b), solder resists 115 are formed by a known method on surfaces of the substrate 111 and the land 112 so as to be positioned in a portion where the solder bonding is not carried out. Each of the solder resists 115 is a member provided so as to protect the wiring on the substrate. A known material may be used to constitute the solder resist 115 as long as the material has an insulating property.

Further, as illustrated in FIG. 7(c), a concave 113 is formed in the land 112. The concave 113 can be formed by a known method. For example, etching is carried out so as to form the concave 113.

Next, as illustrated in FIG. 7(d), a nickel plate layer 114 is formed on the concave 113. At this time, the nickel plate layer 114 is formed so that its thicker is larger than the concave depth L1 of the concave 113. The nickel plate thickness L2 is larger than the concave depth L1 by 1 μm or more. That is, the plating is carried out so that the layer thickness difference L3 is 1 μm or more. This arrangement is realized by setting at least either the depth of the concave 113 or the thickness of the nickel plate layer 114. The nickel plate layer 114 may be formed by a known method. For example, electroless plating may be carried out so as to form the nickel plate layer 114.

Further, as illustrated in FIG. 7(e), solder bonding is carried out, by using the tin-containing solder 131, with respect to the portion where the solder bonding is carried out. The solder bonding can be carried out by a known method. As the tin-containing solder 131, it is preferable to use a solder generally referred to as “lead-free solder”. An example thereof is a tin-containing solder such as Sn—Ag—Cu alloy. As the tin-containing solder 131 of the present embodiment, it is preferable to use a tin-containing lead-free solder such as the Sn—Ag—Cu alloy, but it is possible to use a solder such as a conventional Sn—Pb alloy containing lead or a conventional Sn—Pb—Ag alloy containing lead. FIG. 7(e) does not illustrate a member to be solder bonded, but the solder bonding may be carried out with respect to any member by using the tin-containing solder 131.

The solder joint of the semiconductor device 100 of the present embodiment is arranged in this manner, so that a crack hardly occurs in the interface p2 and the tin-containing alloy 116. This effect will be detailed in Example 1 and Example 3.

### Embodiment 2

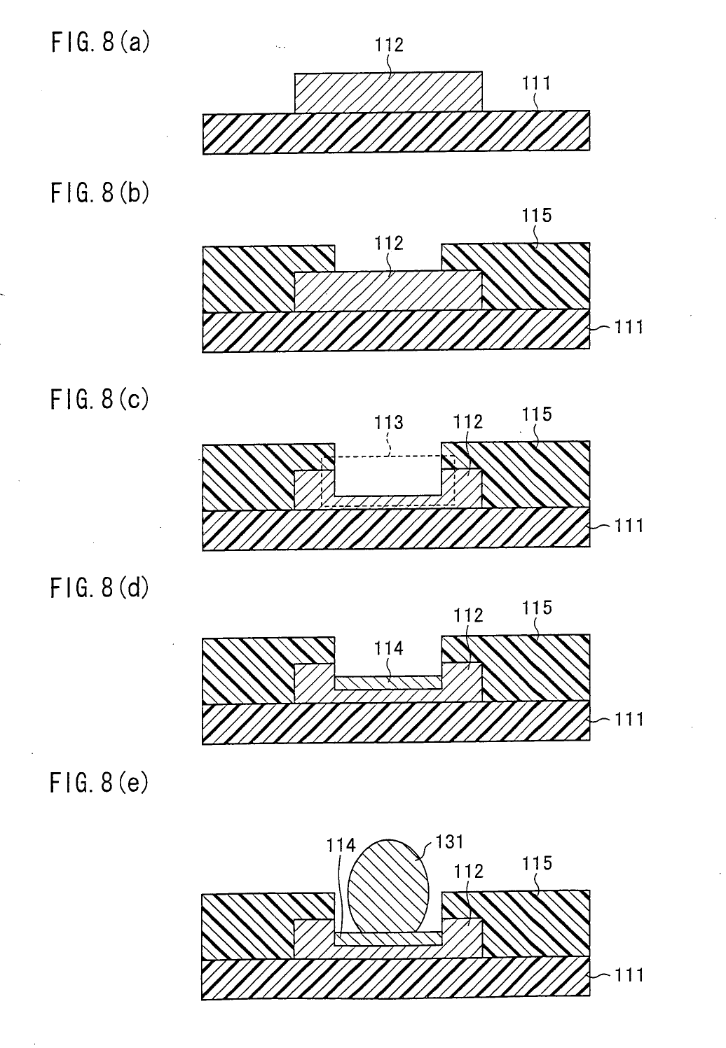

The following description will explain another embodiment of the present invention with reference to FIG. 8 to FIG. 10. Note that, the present embodiment is different from Embodiment 1 only in the below described points. Further, for convenience in descriptions, the same reference numerals are given to members having the same functions as those illustrated in the drawings of Embodiment 1, and descriptions thereof are omitted.

The present embodiment describes the case of the cross sectional shape B illustrated in FIG. 1(b) and FIG. 2.

A solder joint of a semiconductor device 100 of the present embodiment is formed so as to have the cross sectional shape B. That is, a concave 113 is formed in a land 112, and a nickel plate layer 114 is formed so that its thickness is smaller than a depth of concave 113. Further, in case where the layer thickness difference L3 is 1 μm or more, the interface p1 and the interface p2 are deviated from each other by 1 μm or more.

Next, with reference to FIG. 8, the following describes how to carry out solder bonding as in the cross sectional shape B.

FIG. 8 shows cross sectional views illustrating a procedure in which a circuit substrate 110b is formed into the cross sectional shape B so as to carry out the solder bonding.

First, as illustrated in FIG. 8(a), a portion where solder bonding is carried out with respect to a wiring line (i.e., land 112) is formed on a substrate 111 made of a known material such as a glass substrate or an epoxy substrate. Any material may be used to constitute the wiring as long as the material is a known conductive material. Examples of the material include copper and aluminum. Further, the wiring is formed by a known method. For example, a conductor thin film such as a copper foil formed on the substrate 111 is etched so as to form the wiring or a printed wiring is transferred onto the substrate 111. Other known method may be adopted so as to form the wiring.

Next, as illustrated in FIG. 8(b), solder resists 115 are formed by a known method on surfaces of the substrate 111 and the land 112 so as to be positioned in a portion where the solder bonding is not carried out. Each of the solder resist 115 is a member provided so as to protect the wiring on the substrate. A known material may be used to constitute the solder resist 115 as long as the material has an insulating property.

Further, as illustrated in FIG. 8(c), a concave 113 is formed in the land 112. The concave 113 can be formed by a known method. For example, etching is carried out so as to form the concave 113.

Next, as illustrated in FIG. 8(d), a nickel plate layer 114 is formed on the concave 113. At this time, the nickel plate layer 114 is formed so that its thickness is smaller than the concave depth L1 of the concave 113. The nickel plate thickness L2 is smaller than the concave depth L1 by 1 μm or more. That is, the plating is carried out so that the layer thickness difference L3 is 1 μm or larger. This arrangement is realized by setting at least either the depth of the concave 113 or the thickness of the nickel plate layer 114. The nickel plate layer 114 may be formed by a known method. For example, electroless plating may be carried out so as to form the nickel plate layer 114.

Further, as illustrated in FIG. 8(e), solder bonding is carried out, by using the tin-containing solder 131, with respect to the portion where the solder bonding is carried out. The solder bonding can be carried out by a known method. As the tin-containing solder 131, it is preferable to use a solder generally referred to as “lead-free solder”. An example thereof is a tin-containing solder such as Sn—Ag—Cu alloy. As the tin-containing solder 131 of the present embodiment, it is preferable to use a tin-containing lead-free solder such as the Sn—Ag—Cu alloy, but it is possible to use a solder such as a conventional Sn—Pb alloy containing lead or a conventional Sn—Pb—Ag alloy containing lead. FIG. 8(e) does not illustrate a member to be solder bonded, but the solder bonding may be carried out with respect to any member by using the tin-containing solder 131.

The solder joint of the semiconductor device 100 of the present embodiment is arranged in this manner, so that a crack hardly occurs in the interface p2 and the tin-containing alloy 116. This effect will be detailed in Example 2 and Example 4.

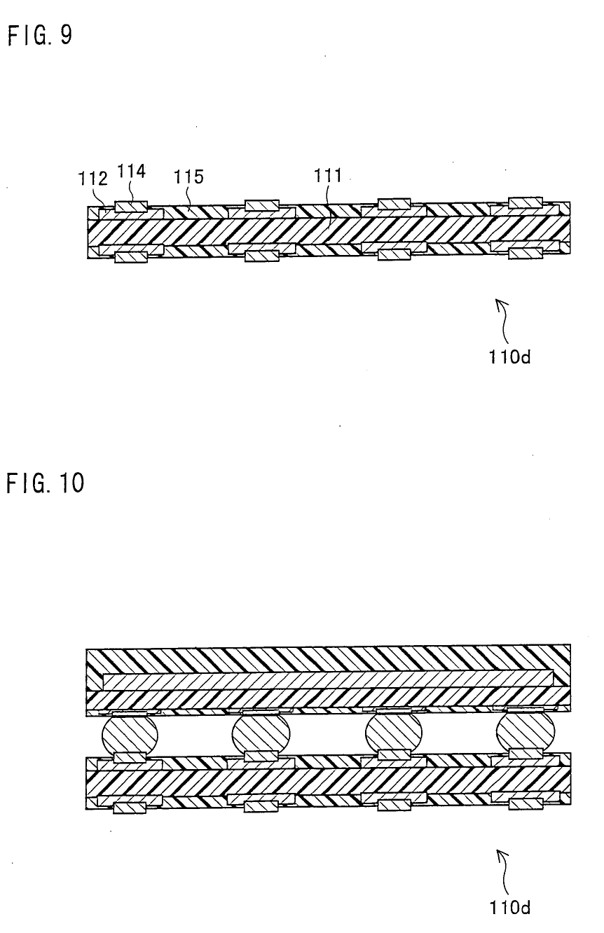

Note that, the embodiment illustrates the arrangement in which the semiconductor chip 120 is provided on the surface of the circuit substrate 110, but it may be so arranged that: as in a circuit substrate 110d of FIG. 9, a land 112, a concave 113, and a nickel plate layer 114 are provided on each of both sides of a substrate 111d, and a solder resist 115 is provided on each of the both sides of the circuit substrate 110d so as to form an external connection terminal 130 on a nickel plate layer 114. Further, it may be so arranged that a semiconductor circuit or circuit substrate is formed in the circuit substrate 110d by a known method.

As illustrated in FIG. 10, this arrangement allows connection reliability of the solder joint to be improved in the semiconductor circuit or the circuit substrate in which a plurality of semiconductor circuits are laminated and connected.

The present invention is not limited to the description of the embodiments above, but may be altered by a skilled person within the scope of the claims. An embodiment based on a proper combination of technical means disclosed in different embodiments is encompassed in the technical scope of the present invention.

### EXAMPLES

### Example 1

Next, the following experiment was carried out so as to show that it is hard to crack the solder joint of the present embodiment which had been provided so as to have the cross sectional shape A.

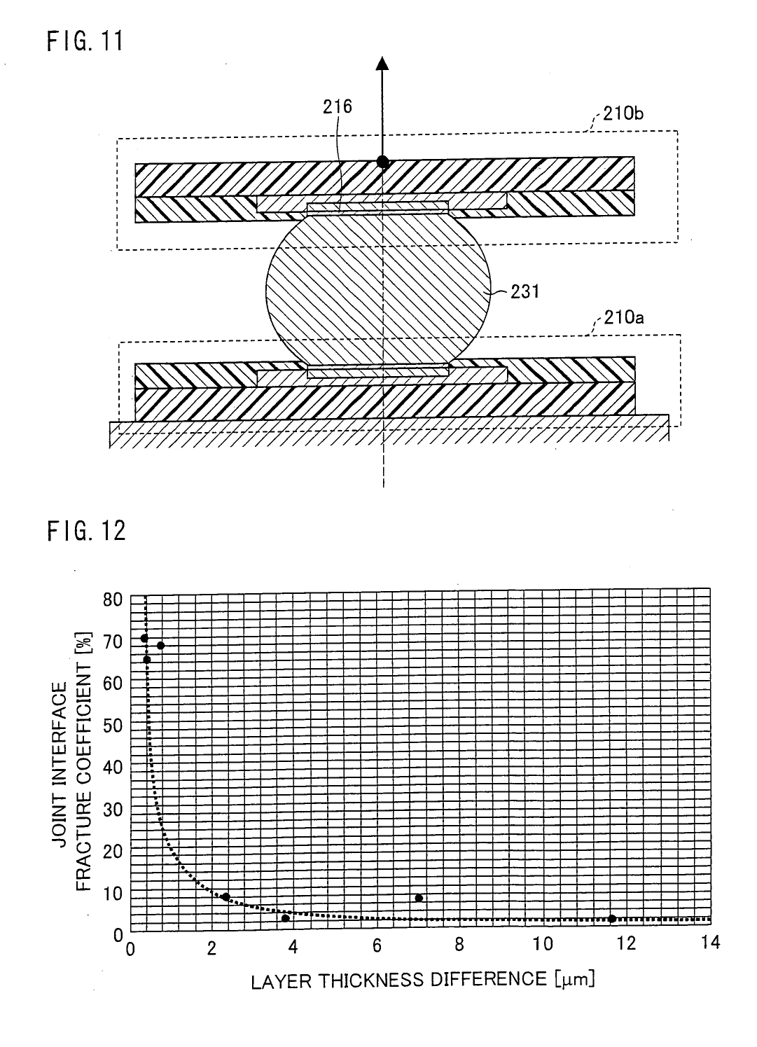

FIG. 11 is a cross sectional view illustrating how to evaluate the connection reliability of the solder joint by fixing one of two circuit substrates 210a and 210b which had been solder bonded in accordance with the method of the present embodiment and by peeling the other one.

In FIG. 11, the two circuit substrates 210 arranged in the same manner were solder bonded to each other by using a tin-containing solder 231, and one of the circuit substrates 210 was fixed on the floor as a circuit substrate 210a. Further, the other one was used as a circuit substrate 210b. The circuit substrate 210b was raised upward, and a load was applied to the solder joint. In the present embodiment, a load as in an impact test was applied to a bonding interface in which solder bonding was carried out. In Example of FIG. 11, the circuit substrate 210b was raised upward until the solder joint cracked and the circuit substrate 210a and the circuit substrate 210b were completely separated from each other, and the load was applied to the solder joint.

The tin-containing alloy layer 216 was more fragile than other metal layer, specifically, than the nickel plate layer 214 or the tin-containing solder 231, so that a crack was likely to occur in case where a stress was applied to the solder joint. Thus, in the metal layer having the solder joint, a ratio at which the tin-containing alloy layer 216 cracks was defined as a joint interface fracture coefficient, and a ratio at which the tin-containing alloy layer 216 in case where the solder joint cracked was evaluated.

Table 1 shows the joint interface fracture coefficient evaluated by the method illustrated in FIG. 11, and this is an example of an experiment carried out with three shapes in view of the concave depth L1 and the nickel plate thickness L2.

TABLE 1

| | Cross sectional | L1 | L2 | L3 | Joint interface fracture |
|---|---|---|---|---|---|
| Sample | shape | [μm] | [μm] | [μm] | coefficient (%) |
| 1 | C | 6.26 | 7.03 | 0.77 | 67.9 |
| 2 | A | 4.46 | 8.28 | 3.82 | 2.6 |
| 3 | A | 4.74 | 16.4 | 11.66 | 1.6 |

In a sample 1, the concave depth L1 was 6.26 μm, the nickel plate thickness L2 was 7.03 μm, and its cross sectional shape was regarded as the cross sectional shape C illustrated in FIG. 1(c).

In a sample 2, the concave depth L1 was 4.46 μm, the nickel plate thickness L2 was 8.28 μm, and its cross sectional shape was regarded as the cross sectional shape A illustrated in FIG. 1(a).

In a sample 3, the concave depth L1 was 4.74 μm, the nickel plate thickness L2 was 16.4 μm, and its cross sectional shape was regarded as the cross sectional shape A illustrated in FIG. 1(a).

In the present Example, the joint interface fracture coefficient was 67.9% in case of the sample 1 (cross sectional shape C), the joint interface fracture coefficient was 2.6% in case of the sample 2 (cross sectional shape A), and the joint interface fracture coefficient was 1.6% in case of the sample 3 (cross sectional shape A). That is, it was found that the tin-containing alloy layer 216 is less likely to crack in the case of the cross sectional shape A than in the case of the cross sectional shape C.

Generally, the tin-containing alloy layer 216 is fragile and is more likely to crack with a less impact than other metal layer. Thus, in case of the cross sectional shape A as described above, a mechanism for alleviating a stress exerted to the tin-containing alloy layer 216 or the interface p2 between the nickel plate layer 214 and the tin-containing alloy layer 216 might work, which resulted in the lower joint interface fracture coefficient. That is, it was proved that the cross sectional shape A improves the connection reliability of the solder joint.

### Example 2

Next, the following experiment was carried out in the same manner as in Example 1 so as to show that it is hard to crack the solder joint of the present embodiment which had been provided so as to have the cross sectional shape B.

Table 2 shows the joint interface fracture coefficient evaluated by the method illustrated in FIG. 11, and this is an example of an experiment carried out with the three shapes in view of the concave depth L1 and the nickel plate thickness L2.

TABLE 2

| | Cross sectional | L1 | L2 | L3 | Joint interface fracture |
|---|---|---|---|---|---|
| Sample | shape | [μm] | [μm] | [μm] | coefficient (%) |
| 4 | B | 8.73 | 6.36 | 2.37 | 7.9 |
| 5 | C | 9.21 | 8.86 | 0.35 | 69.8 |
| 6 | A | 8.51 | 15.54 | 7.03 | 6.8 |

In a sample 4, the concave depth L1 was 8.73 μm, the nickel plate thickness L2 was 6.36 μm, and its cross sectional shape was regarded as the cross sectional shape B illustrated in FIG. 1(b).

In a sample 5, the concave depth L1 was 9.21 μm, the nickel plate thickness L2 was 8.86 μm, and its cross sectional shape was regarded as the cross sectional shape C illustrated in FIG. 1(c).

In a sample 6, the concave depth L1 was 8.51 μm, the nickel plate thickness L2 was 15.54 μm, and its cross sectional shape was regarded as the cross sectional shape A illustrated in FIG. 1(a).

In the present Example, the joint interface fracture coefficient was 69.8% in case of the sample 5 (cross sectional shape C), the joint interface fracture coefficient was 7.9% in case of the sample 4 (cross sectional shape B). Further, the joint interface fracture coefficient was 6.8% in case of the sample 6 (cross sectional shape A). That is, it was found that the tin-containing alloy layer 216 is less likely to crack in the case of the cross sectional shape A or the cross sectional shape B than in the case of the cross sectional shape C.

Generally, the tin-containing alloy layer 216 is fragile and is more likely to crack with a less impact than other metal layer. Thus, in case of the cross sectional shape A or the cross sectional shape B as described above, a mechanism for alleviating a stress exerted to the tin-containing alloy layer 216 or the interface p2 between the nickel plate layer 214 and the tin-containing alloy layer 216 might work, which resulted in the lower joint interface fracture coefficient.

Particularly in case of the sample 4, the tin-containing alloy layer 216 had the thickness of about 2 to 4 μm, so that the tin-containing alloy layer 216 was formed so as to be positioned near to the interface p1 between the land 211 and the solder resist 215, and this arrangement was similar to the cross sectional shape C. However, the layer thickness difference L3 was 2.37 μm, so that the interface p2 was positioned away from the interface p1. Thus, the mechanism for alleviating the stress exerted to the interface p2 might lower the joint interface fracture coefficient. That is, it was proved that the cross sectional shape A or the cross sectional shape B improves the connection reliability of the solder joint.

FIG. 12 is a graph illustrating a relation between the layer thickness difference L3 and the joint interface fracture coefficient in the experiments which were carried out in Example 1 and Example 2. As illustrated in FIG. 12, when the layer thickness difference L3 was equal to or larger than 2 μm, the joint interface fracture coefficient was suppressed to 10% or less. Further, according to an approximate curve estimated from resultant values of FIG. 12, it is found that: the joint interface fracture coefficient was about 60% when the layer thickness difference L3 was about 0.4 μm, but the joint interface fracture coefficient was about 20% when the layer thickness difference L3 was about 1 μm, and the joint interface fracture coefficient dropped to 4% when the layer thickness difference L3 was about 4 μm.

### Example 3

Next, a stress analysis was carried out through simulation so as to show it is hard to crack the solder joint of the present embodiment which had been formed so as to have the cross sectional shape A.

An analysis model based on the state illustrated in FIG. 11 was prepared. Table 3 shows analysis results obtained through simulation carried out in view of the three shapes.

TABLE 3

| | Cross | | | | Stress exerted to |
|---|---|---|---|---|---|
| | sectional | L1 | L2 | L3 | interface p2 |
| Sample | shape | [μm] | [μm] | [μm] | [×10⁸ N/m²] |
| s1 | C | 2 | 2 | 0 | 3.0 |
| s2 | A | 2 | 6 | 4 | 2.0 |
| s3 | A | 2 | 12 | 10 | 1.4 |

In a sample s1, the concave depth L1 was 2 μm, the nickel plate thickness L2 was 2 μm, and its cross sectional shape was regarded as the cross sectional shape C illustrated in FIG. 1(c).

In a sample s2, the concave depth L1 was 2 μm, the nickel plate thickness L2 was 6 μm, and its cross sectional shape was regarded as the cross sectional shape A illustrated in FIG. 1(a).

In a sample s3, the concave depth L1 was 2 μm, the nickel plate thickness L2 was 12 μm, and its cross sectional shape was regarded as the cross sectional shape A illustrated in FIG. 1(a).

As a result of the simulation, a stress exerted to the interface p2 between the nickel plate layer 214 and the tin-containing alloy layer 216 was 3.0×10⁸N/m² in the sample s1 having the cross sectional shape C. While, the stress was 2.0×10⁸N/m² in the sample s2 having the cross sectional shape A, and the stress was 1.4×10⁸N/m² in the sample s3.

That is, it was proved that the stress exerted to the interface p2 is smaller in the cross sectional state A (the sample s2 or the sample s3) than the cross sectional state C (the sample s1) whose layer thickness L3 is small.

Thus, the results of the experiment carried out in Example 1 and the results of the simulation carried out in the present Example show that: the method in which an etching amount (etching depth) in the land is larger than the thickness of the nickel plate layer suppresses a crack of the solder joint and improves the connection reliability. That is, this method improves a connection yield of the solder joint.

### Example 4

Next, a stress analysis was carried out through simulation so as to show it is hard to crack the solder joint of the present embodiment which had been formed so as to have the cross sectional shape B.

An analysis model based on the state illustrated in FIG. 11 was prepared. Table 4 shows analysis results obtained through simulation carried out in view of the three shapes.

TABLE 4

| | Cross | | | | Stress exerted to |
|---|---|---|---|---|---|
| | sectional | L1 | L2 | L3 | interface p2 |
| Sample | shape | [μm] | [μm] | [μm] | [×10⁸ N/m²] |
| s4 | B | 6 | 2 | 4 | 1.3 |
| s5 | C | 6 | 6 | 0 | 3.0 |
| s6 | A | 6 | 12 | 6 | 1.8 |

In a sample s4, the concave depth L1 was 6 μm, the nickel plate thickness L2 was 2 μm, and its cross sectional shape was regarded as the cross sectional shape B illustrated in FIG. 1(b).

In a sample s5, the concave depth L1 was 6 μm, the nickel plate thickness L2 was 6 μm, and its cross sectional shape was regarded as the cross sectional shape C illustrated in FIG. 1(c).

In a sample s6, the concave depth L1 was 6 μm, the nickel plate thickness L2 was 12 μm, and its cross sectional shape was regarded as the cross sectional shape A illustrated in FIG. 1(a).

As a result of the simulation, a stress exerted to the interface p2 between the nickel plate layer 214 and the tin-containing alloy layer 216 was 3.0×10⁸N/m² in the sample s5 having the cross sectional shape C. While, the stress was 1.3×10⁸N/m² in the sample s4 having the cross sectional shape B. Note that, the stress was 1.8×10⁸N/m² in the sample s6 having the cross sectional shape A.

That is, it was proved that the stress exerted to the interface p2 is smaller in the cross sectional shape A (the sample s6) or the cross sectional shape B (sample s4) than the cross sectional shape C (the sample s5) whose layer thickness L3 is small.

Thus, the results of the experiment carried out in Example 1 and the results of the simulation carried out in the present Example show that: the method in which an etching amount (etching depth) in the land is larger than the thickness of the nickel plate layer suppresses a crack of the solder joint and improves the connection reliability. That is, this method improves a connection yield of the solder joint.

Particularly in case of the sample s4, the analysis was carried out in view of the state in which the tin-containing alloy layer 216 had the thickness of 4 μm. In this case, the interface p3 between the tin-containing alloy layer 216 and the tin-containing solder 231 was positioned at the same height as the interface p1 between the land 212 and the solder resist 215, so that this arrangement is similar to the cross sectional shape C. However, the layer thickness difference L3 was 4 μm, so that the interface p2 was positioned away from the interface p1. Thus, the mechanism for alleviating the stress exerted to the interface p2 might lower the joint interface fracture coefficient. That is, it was proved that the cross sectional shape A or the cross sectional shape B improves the connection reliability of the solder joint.

Thus, the results of the experiment carried out in Example 2 and the results of the simulation carried out in the present Example show that: the method in which an etching amount (etching depth) in the land is larger than the thickness of the nickel plate layer suppresses a crack of the solder joint and improves the connection reliability. That is, this method improves a connection yield of the solder joint.

Note that, values in the arrangements used in the Examples are mere examples, so that it is so conceivable that the values and results may vary depending on methods and conditions that are adopted. However, it is needless to say that the same effect can be obtained as long as the methods and conditions are adopted within the scope of claims.

Thus, the present invention is not limited to the description of the embodiments above, but may be altered by a skilled person within the scope of the claims. An embodiment based on a proper combination of technical means disclosed in different embodiments is encompassed in the technical scope of the present invention.

As described above, the depth of the concave formed in the land which is to be solder bonded and the thickness of the nickel plate layer on the land are controlled, and the tin-containing alloy layer or the interface between the nickel plate layer and the tin-containing alloy layer is positioned away from the surface position of the land which surface position is free from the concave, thereby forming a structure which allows the solder joint to less crack. Thus, it is possible to provide a crack-resistant solder joint, a circuit substrate having the solder joint, a semiconductor device, and a manufacturing method of the solder joint.

Further, in case of providing a semiconductor device and a semiconductor device substrate each of which has a tin-containing solder as an external connection terminal, a solder joint is formed in the foregoing manner, so that the connection reliability of the solder joint is greatly improved and also an yield in manufacturing the solder joint is improved.

Further, also in case where the tin-containing alloy layer or the interface between the tin-containing alloy layer and the tin-containing solder is formed on the solder joint so as to be positioned near to a surface position of the land which surface position is free from the concave, the connection reliability of the solder joint is improved and the connection yield is improved as long as the interface between the nickel plate layer and the tin-containing alloy layer is deviated from the surface position of the land by 2 μm or more.

As described above, the electronic component of the present embodiment is arranged so that: the solder joint has a concave recessed from the reference surface, and one or more metal layers are laminated on a surface of the concave, and a position of an interface between (i) a tin-containing alloy layer formed on a surface of the metal layer in solder bonding the metal layer and (ii) the metal layer deviates from a plane including the reference surface.

That is, the solder joint of the present embodiment, as described above, has a concave recessed from the reference surface, and one or more metal layers are laminated on a surface of the concave, and a position of an interface between (i) a tin-containing alloy layer formed on a surface of the metal layer in solder bonding the metal layer and (ii) the metal layer deviates from a plane including the reference surface.

It may be so arranged that the metal layer is provided so as to be positioned higher than the reference so that the surface of the metal layer is positioned outside the concave, or it may be so arranged that the metal layer is provided so as to be positioned lower than the reference surface so that the surface of the metal layer is positioned inside the concave, for example.

That is, the object can be achieved by realizing such an arrangement that at least either a depth of the concave or a thickness of the metal layer is set.

With the above-described arrangement, it is possible to partially alleviate a mechanical stress exerted to the tin alloy layer and the interface between the tin alloy layer and the metal layer, so that it is possible to prevent occurrence of a crack in the structurally fragile tin alloy layer and the interface between the tin alloy layer and the metal layer.

Further, it may be so arranged that the position of the interface between the tin alloy layer and the metal layer deviates from the plane including the reference surface by 2 μm or more.

This makes it possible to partially alleviate a mechanical stress exerted to the structurally fragile tin alloy layer and the interface between the tin alloy layer and the metal layer, so that it is possible to prevent occurrence of a crack in the solder.

Further, it may be so arranged that the position of the interface between the first metal layer and the second metal layer deviates from the plane including the reference surface by 2 μm or more.

This makes it possible to effectively deviate the position of the interface between the first metal layer and the second metal layer, on which the structurally fragile tin alloy layer is formed, from the plane including the reference surface, so that it is possible to partially alleviate the stress exerted to the interface. Thus, it is possible to further prevent occurrence of a crack in the solder.

Note that, the metal layer may be arranged so that the first metal layer and the second metal layer are laminated sequentially from the surface of the concave, or the metal layer may contain nickel, or the metal layer may contain gold.

Further, it may be so arranged that the first metal layer contains nickel and the second metal layer contains gold.

This allows the concave formed in the electrode to be covered by the metal layer made of metal containing nickel or metal containing gold, so that it is possible to improve the metal layer's wettability with respect to the solder. Particularly If the metal layer containing gold is provided on the metal layer containing nickel, it is possible to improve the metal layer's wettability with respect to the solder without being influenced by a fragile alloy layer formed by providing the metal layer containing gold directly on the concave of the electrode.

Further, it may be so arranged that the electrode is made of copper or copper-containing alloy.

Further, it may be so arranged that the electronic component is a circuit substrate.

With the above-described arrangement, it is possible to prevent the solder from cracking in the solder joint formed on the circuit substrate. Thus, the connection reliability of the solder joint is greatly improved and an yield in manufacturing a circuit with the circuit substrate is improved. Further, the reliability of a device manufactured with the circuit substrate and the yield in manufacturing the device are improved.

Further, it may be so arranged that the solder joint is provided on a rear surface of the circuit substrate.

This makes it possible to improve the connection reliability of the solder joint also in a semiconductor circuit or a circuit substrate in which a plurality of semiconductor circuits are laminated and connected. Thus, the connection reliability of the solder joint is greatly improved and an yield in manufacturing a circuit with the circuit substrate is improved. Further, the reliability of a device manufactured with the circuit substrate and the yield in manufacturing the device are improved.

Further, it may be so arranged that an external connection terminal is soldered so as to be provided on the solder joint of the circuit substrate.

This allows the external connection terminal formed on the circuit substrate to be constituted of the solder joint of the present embodiment, which has high connection reliability. Therefore, the connection reliability of the solder joint is greatly improved and an yield in manufacturing a circuit with the circuit substrate is improved. Further, the reliability of a device manufactured with the circuit substrate and the yield in manufacturing the device are improved.

Further, as described above, the semiconductor device of the present embodiment is arranged so that a semiconductor element is solder bonded to the solder joint of the electronic component.

With the above-described arrangement, it is possible to prevent the circuit substrate or the solder from cracking, so that the connection reliability of the solder joint is greatly improved. Thus, the connection reliability of the solder joint of the manufactured semiconductor device is greatly improved, so that an yield in manufacturing a circuit with the semiconductor device is improved. Further, the reliability of a device manufactured with the semiconductor device and an yield in manufacturing a device with the semiconductor device is improved.

Further, as described above, the solder joint of the present embodiment is provided on an electrode having a flat reference surface, wherein the solder joint has a concave recessed from the reference surface, and one or more metal layers are laminated on a surface of the concave, and a position of an interface between (i) a tin alloy layer formed on a surface of the metal layer in solder bonding the metal layer and (ii) the metal layer deviates from a plane including the reference surface.

Further, as described above, the solder joint of the present embodiment is provided on an electrode having a flat reference surface, wherein the solder joint has a concave recessed from the reference surface, and a first metal layer and a second metal layer are laminated sequentially from a surface of the concave, and a position of an interface between the first metal layer and the second metal layer in solder bonding the metal layer deviates from a plane including the reference surface.

Note that, the metal layer may contain nickel, or the metal layer may be arranged so that the first metal layer contains nickel and the second metal layer contains gold.

This allows the concave formed on the electrode to be covered by the metal layer made of metal containing nickel or metal containing gold, so that it is possible to improve the metal layer's wettability with respect to the solder. Particularly If the metal layer containing gold is provided on the metal layer containing nickel, it is possible to improve the metal layer's wettability with respect to the solder without being influenced by a fragile alloy layer formed by providing the metal layer containing gold directly on the concave of the electrode.

Further, a method of the present embodiment for manufacturing an electronic component (the method is referred to as “first manufacturing method”), as described above, includes the steps of: (i) forming a concave recessed in an electrode having a flat reference surface; (ii) forming one or more metal layers on a surface of the concave; and (iii) solder bonding the metal layer, wherein (1) the metal layer is positioned higher than the reference surface or (2) the metal layer is positioned lower than the reference surface in the step (ii), and a position of an interface between (a) a tin alloy layer formed on a surface of the metal layer in solder bonding the metal layer and (b) the metal layer deviates from a plane including the reference surface in the step (iii).

Further, a method of the present embodiment for manufacturing an electronic component (the method is referred to as “second manufacturing method”), as described above, includes the steps of: (i) forming a concave recessed in an electrode having a flat reference surface; (ii) forming one or more metal layers on a surface of the concave; and (iii) solder bonding the metal layer, wherein (3) a first metal layer is provided on the surface of the concave so as to be positioned higher than the reference surface and a second metal layer is further provided or (4) the first metal layer is provided on the surface of the concave so as to be positioned lower than the reference surface and the second metal layer is further provided in the step (ii), and a position of an interface between the first metal layer and the second metal layer deviates from a plane including the reference surface in the step (iii).

According to the first manufacturing method or the second manufacturing method, a position of the tin alloy layer which is fragile with respect to a mechanical stress and the position of the interface between the tin alloy layer and the metal layer can be deviated from the plane including the reference surface. This makes it possible to partially alleviate the mechanical stress exerted to the tin alloy layer and the interface between the tin alloy layer and the metal layer. That is, it is possible to prevent the solder from cracking in the structurally fragile tin alloy layer and the interface between the tin alloy layer and the metal layer.

Therefore, in the present embodiment, it is possible to provide a crack-resistant solder joint, an electronic component such as a circuit substrate having the solder joint, a semiconductor device, and a manufacturing method of the electronic component.

Further, the first manufacturing method may be arranged so that the metal layer is made of metal containing nickel, metal containing gold, or both metal containing nickel and metal containing gold.

Further, the second manufacturing method may be arranged so that the first metal layer contains nickel and the second metal layer contains gold.

This allows the concave formed on the electrode to be covered by the metal layer made of metal containing nickel or metal containing gold, so that it is possible to improve the metal layer's wettability with respect to the solder. Particularly If the metal layer containing gold is provided on the metal layer containing nickel, it is possible to improve the metal layer's wettability with respect to the solder without being influenced by a fragile alloy layer formed by providing the metal layer containing gold directly on the concave of the electrode.

As described above, in the present invention, the depth of the concave formed in the land to be solder bonded and the thickness of the nickel plate on the land are controlled, and the tin-containing alloy layer or the interface between the nickel plate layer and the tin-containing alloy layer is deviated from the surface position of land which surface position is free from the concave, so that it is possible to form the mechanism which hardly allows occurrence of a crack in the solder joint. Thus, the present invention is applicable to a circuit substrate in which soldering is carried out or to a semiconductor joint of a semiconductor device, so that it is possible to improve the connection reliability of the solder joint.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. An electronic component, comprising an electrode having a flat reference surface and a solder joint to be solder bonded,
said solder joint having a concave recessed from the reference surface,
one or more metal layers being laminated on a surface of the concave,
a position of an interface between (a) a tin alloy layer formed on a surface of the metal layer in solder bonding the metal layer and (b) the metal layer deviating from a plane including the reference surface.

2. The electronic component as set forth in claim 1, wherein
the solder joint has the metal layers including a first metal layer and a second metal layer laminated sequentially from the surface of the concave, and
a position of an interface between the first metal layer and the second metal layer in solder bonding the metal layers deviates from a plane including the reference surface.

3. The electronic component as set forth in claim 1, wherein the metal layer is positioned higher than the reference surface and the surface of the metal layer is positioned outside the concave.

4. The electronic component as set forth in claim 1, wherein the metal layer is positioned lower than the reference surface and the surface of the metal layer is positioned inside the concave.

5. The electronic component as set forth in claim 1, wherein the position of the interface between the tin alloy layer and the metal layer deviates from the plane including the reference surface by 2 μm or more.

6. The electronic component as set forth in claim 2, wherein the position of the interface between the first metal layer and the second metal layer deviates from the plane including the reference surface by 2 μm or more.

7. The electronic component as set forth in claim 1, wherein the metal layer contains nickel.

8. The electronic component as set forth in claim 1, wherein the metal layer contains gold.

9. The electronic component as set forth in claim 2, wherein the first metal layer contains nickel and the second metal layer contains gold.

10. The electronic component as set forth in claim 1, wherein the electrode is made of copper or copper-containing alloy.

11. The electronic component as set forth in claim 1, wherein the electronic component is a circuit substrate.

12. The electronic component as set forth in claim 11, wherein the solder joint is provided on a rear surface of the circuit substrate.

13. The electronic component as set forth in claim 11, wherein an external connection terminal is soldered so as to be provided on the solder joint of the circuit substrate.

14. A semiconductor device, comprising an electronic component including an electrode having a flat reference surface and a solder joint to be solder bonded, the solder junction of the electronic component being solder bonded to a semiconductor element,
said solder joint having a concave recessed from the reference surface,
one or more metal layers being laminated on a surface of the concave,
a position of an interface between (a) a tin alloy layer formed on a surface of the metal layer in solder bonding the metal layer and (b) the metal layer deviating from a plane including the reference surface.

15. A solder joint, being provided on an electrode having a flat reference surface,
said solder joint having a concave recessed from the reference surface,
one or more metal layers being laminated on a surface of the concave,
a position of an interface between (a) a tin alloy layer formed on a surface of the metal layer in solder bonding the metal layer and (b) the metal layer deviating from a plane including the reference surface.

16. The solder joint as set forth in claim 15, wherein the metal layers includes a first metal layer and a second metal layer laminated sequentially from the surface of the concave, and
a position of an interface between the first metal layer and the second metal layer in solder bonding the metal layers deviates from a plane including the reference surface.

17. The solder joint as set forth in claim 15, wherein the metal layer contains nickel.

18. The solder joint as set forth in claim 16, wherein the first metal layer contains nickel and the second metal layer contains gold.

19. A method for manufacturing an electronic component, comprising the steps of:
(i) forming a concave recessed in an electrode having a flat reference surface;
(ii) forming one or more metal layers on a surface of the concave; and
(iii) solder bonding the metal layer, wherein
the metal layer is positioned higher or lower than the reference surface in the step (ii), and
a position of an interface between (a) a tin alloy layer formed on a surface of the metal layer in solder bonding the metal layer and (b) the metal layer deviates from a plane including the reference surface in the step (iii).

20. The method as set forth in claim 19, wherein the metal layer is made of metal containing nickel, metal containing gold, or both metal containing nickel and metal containing gold.

21. A method for manufacturing an electronic component, comprising the steps of:
(i) forming a concave recessed in an electrode having a flat reference surface;
(ii) forming one or more metal layers on a surface of the concave; and
(iii) solder bonding the metal layer, wherein
a first metal layer is provided on the surface of the concave so as to be positioned higher or lower than the reference surface and a second metal layer is further provided in the step (ii), and
a position of an interface between the first metal layer and the second metal layer deviates from a plane including the reference surface in the step (iii).

22. The method as set forth in claim 21, wherein the first metal layer contains nickel and the second metal layer contains gold.
